(19) United States
(12) Patent Application Publication
(10) Pub. No.: US 2012/0070589 A1
(43) Pub. Date: Mar. 22, 2012

(54) CREATION OF MAGNETIC FIELD (VECTOR POTENTIAL) WELL FOR IMPROVED PLASMA DEPOSITION AND RESPUTTERING UNIFORMITY

(76) Inventors: Liqi Wu, Santa Clara, CA (US); Ishtak Karim, San Jose, CA (US); Huatan Qiu, Dublin, CA (US); Kie-Jin Park, San Jose, CA (US); Chunming Zhou, Milpitas, CA (US); Karthik Colinjivadi, San Jose, CA (US)

(21) Appl. No.: 13/224,077

(22) Filed: Sep. 1, 2011

Related U.S. Application Data
(60) Provisional application No. 61/384,917, filed on Sep. 21, 2010.

(51) Int. Cl. C23C 14/14; C23C 14/48

(52) U.S. Cl. 427/530; 118/723 R; 427/523

(57) ABSTRACT

A physical vapor deposition (PVD) system includes a chamber and a target arranged in a target region of the chamber. A pedestal has a surface for supporting a substrate and is arranged in a substrate region of the chamber. A transfer region is located between the target region and the substrate region. N coaxial coils are arranged in a first plane parallel to the surface of the pedestal and below the pedestal. M coaxial coils are arranged adjacent to the pedestal. N currents flow in a first direction in the N coaxial coils, respectively, and M currents flow in a second direction in the M coaxial coils that is opposite to the first direction, respectively.

### CROSS-REFERENCE TO RELATED APPLICATIONS

This application claims the benefit of U.S. Provisional Application No. 61/384,917, filed on Sep. 21, 2010. The disclosure of the above application is incorporated herein by reference in its entirety.

### FIELD

The present disclosure relates to ionized physical vapor deposition (PVD) systems and methods.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Ionized physical vapor deposition (PVD) in magnetron systems confines high density plasma in both a target region and a transfer region using balanced magnetic fields. The magnetic fields are generated by electromagnetic coils or permanent magnets, which are typically located around a periphery of a deposition chamber. The plasma in the target region is leaked and transferred through magnetic null points (where the field approximately vanishes) created in the vicinity of the target. The plasma escaping from narrow magnetic orifices forms a beam with a steep radial profile. Under certain conditions, a circular magnetic null is created to improve on-wafer and in-feature performance of a film.

A typical magnetron system with coaxial electromagnetic coil sets forms a magnetic field profile that has a non-zero magnetic field in a central region of the deposition chamber and an increasing magnetic field with increasing radius. The strong field at walls of the deposition chamber keeps the plasma away from the walls. However, the finite field in the central region prevents charged species from diffusing much. As a result, domed deposition and resputtering profiles may occur along with poor deposition uniformity across the substrate.

If the magnetic field is weakened enough around the central region to allow for charged species diffusion, the magnetic field near the chamber walls also typically decreases enough to become ineffective in confining the plasma. This leads to deposition flux with low ion content, which causes poor film quality, step coverage, and continuity on patterned features.

### SUMMARY

A physical vapor deposition (PVD) system according to the present disclosure includes a chamber. A target is arranged in a target region of the chamber. A pedestal has a surface for supporting a substrate and is arranged in a substrate region of the chamber. A transfer region is located between the target region and the substrate region. N coaxial coils are arranged in a first plane parallel to the surface of the pedestal and below the pedestal. M coaxial coils are arranged adjacent to the pedestal. N and M are integers greater than zero. N currents flow in a first direction in the N coaxial coils, respectively, and M currents flow in a second direction in the M coaxial coils that is opposite to the first direction, respectively.

In other features, the M coaxial coils are arranged in a second plane that is parallel to the surface of the pedestal and above the surface of the pedestal.

In other features, the M coaxial coils are arranged in a second plane that is parallel to the surface of the pedestal and below the surface of the pedestal.

In other features, at least some of the M coaxial coils are arranged in a second plane that is parallel to the surface of the pedestal and below the surface of the pedestal, and remaining ones of the M coaxial coils are arranged in a third plane that is parallel to the surface of the pedestal and above the surface of the pedestal.

In other features, the N coaxial coils and the M coaxial coils create a magnetic field well in the chamber above the substrate. The magnetic field well is generally “U”-shaped and is centered on a top surface of the pedestal. A magnetic null is located inside the magnetic field well. A strong magnetic field is located outside of the magnetic field well.

In other features, at least one of the N coaxial coils has a first diameter, at least one of the M coaxial coils has a second diameter, and the second diameter is greater than the first diameter. The target includes a hollow cathode magnetron (HCM). A smallest one of the M currents is greater than a greatest one of the N currents. A smallest one of the M currents is approximately two times a greatest one of the N currents. The N coaxial coils and the M coaxial coils are arranged 0-6 inches below and above the surface of the pedestal, respectively.

In other features, the N coaxial coils and the at least some of the M coaxial coils are arranged below the surface of the pedestal and are coplanar. The N coaxial coils and the at least some of the M coaxial coils are arranged 0-6 inches below the surface of the pedestal. The N coaxial coils and the at least some of the M coaxial coils are arranged approximately 1 inch below the surface of the pedestal.

A method of operating a physical vapor deposition (PVD) system includes arranging N coaxial coils in a first plane parallel to a surface of a pedestal in a chamber of a PVD system and below the pedestal; arranging M coaxial coils adjacent to the pedestal; and creating a magnetic field well above the substrate by supplying N currents to the N coaxial coils, respectively, and M currents to the M coaxial coils, respectively. N and M are integers greater than zero. The N currents flow in a first direction in the N coaxial coils and the M currents flow in a second direction in the M coaxial coils that is opposite to the first direction.

In other features, arranging the M coaxial coils includes arranging the M coaxial coils in a second plane that is parallel to the surface of the substrate and above the surface of the pedestal.

In other features, arranging the M coaxial coils includes arranging the M coaxial coils in a second plane that is parallel to the surface of the substrate and below the surface of the pedestal.

In other features, arranging the M coaxial coils includes arranging at least some of the M coaxial coils in a second plane that is parallel to the surface of the pedestal and below the surface of the pedestal and arranging remaining ones of the M coaxial coils in a third plane that is parallel to the surface of the pedestal and above the surface of the pedestal.

In other features, the magnetic field well is generally “U”-shaped and is centered on a top surface of the pedestal. A magnetic null is located inside the magnetic field well. A strong magnetic field is located outside of the magnetic field well.

In other features, at least one of the N coaxial coils has a first diameter, at least one of the M coaxial coils has a second diameter, and the second diameter is greater than the first diameter.

In other features, the PVD system includes a hollow cathode magnetron (HCM) target. A smallest one of the M currents is greater than a greatest one of the N currents. The N coaxial coils and the at least some of the M coaxial coils are arranged 0-6 inches below and above the surface of the pedestal, respectively.

In other features, the N coaxial coils and the at least some of the M coaxial coils are arranged below the surface of the pedestal and are coplanar. The N coaxial coils and the at least some of the M coaxial coils are arranged 0-6 inches below the surface of the pedestal. The N coaxial coils and the at least some of the M coaxial coils are arranged approximately 1 inch below the surface of the pedestal.

Further areas of applicability of the present disclosure will become apparent from the detailed description provided hereinafter. It should be understood that the detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIGS. 1-2 are cross-sectional views of physical vapor deposition (PVD) systems according to the present disclosure;

FIG. 3 includes a first graph showing magnetic confinement potential and a second graph showing plasma density;

FIG. 4 is a graph showing etch rate in normalized units (NU) as function of an inner diameter of the coaxial coils below a pedestal;

FIG. 5 is a graph showing deposition rate in NU as function of an inner diameter of the coaxial coils below the pedestal;

FIGS. 6 and 7 are plots showing simulated normalized magnetic field strengths and magnetic wells in the chamber with opposite polarities on the upper and lower coaxial coils; and

FIG. 8 illustrates an etch rate profile.

### DETAILED DESCRIPTION

The following description is merely illustrative in nature and is in no way intended to limit the disclosure, its application, or uses. For purposes of clarity, the same reference numbers will be used in the drawings to identify similar elements. As used herein, the phrase at least one of A, B, and C should be construed to mean a logical (A or B or C), using a non-exclusive logical OR. It should be understood that steps within a method may be executed in different order without altering the principles of the present disclosure.

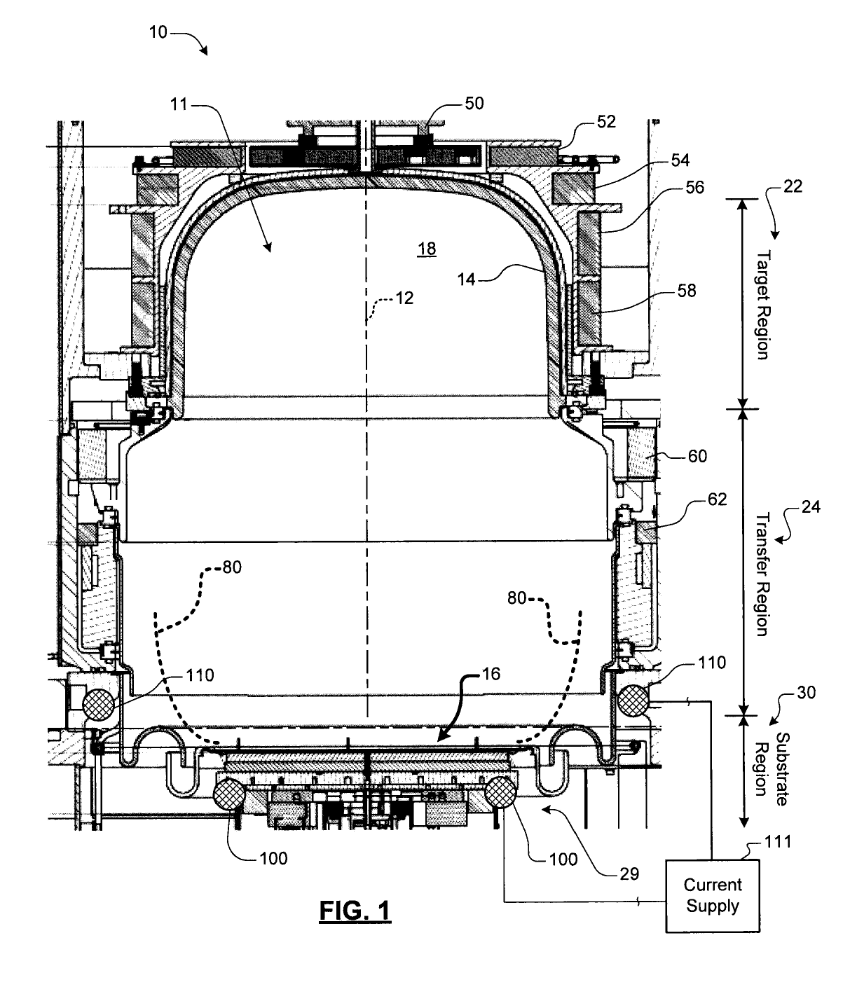

Referring now to FIG. 1, an exemplary PVD system is shown. As can be appreciated, while a Hollow Cathode Magnetron (HCM) PVD system 10 is shown, the present disclosure applies to other PVD systems. The HCM PVD system 10 includes a chamber 11, is generally symmetric about a central axis 12, and typically includes a cathode and an anode.

The cathode includes a target 14, which provides material to be deposited onto a substrate 16. For example only, the target 14 can be made of aluminum, tantalum, titanium, copper or other suitable target material. For HCM applications, the target 14 may have a hollow non-planar shape as shown, although other arrangements are contemplated.

Plasma is generated in the HCM PVD system 10 by introducing a plasma feed gas, such as Argon, into a container portion 18 of the cathode. For example only, a negative bias may be applied to the cathode while holding the chamber at ground potential. For example only, a voltage supply (not shown) may supply a negative DC voltage across the target 14 and an adapter ring. The adapter ring and the chamber 11 may be connected to chassis ground or another reference potential. The anode is typically allowed to float. In other words, the anode is neither grounded nor biased. As a result, an electric field is generated across the plasma feed gas. For example only, the negative bias may be on the order of −100 VDC to −600 VDC, although other bias voltages may be used.

The negative bias on the cathode accelerates positive ions of the formed plasma towards the target 14 to sputter atoms from the target in a target region 22. The sputtered atoms may or may not become ionized, and a subset of them subsequently travels through a transfer region 24 and onto the substrate 16 arranged in a substrate region 30.

One or more permanent magnets 50 may be rotated relative to the central axis 12 to provide a rotating magnetic field in the target region of the chamber 11. Electromagnetic coils or permanent magnets may also be used to control the magnetic field at various points of the chamber 11. Since the substrate 16 is usually a circular substrate, coaxial electromagnetic coils or an array of permanent magnets may be used.

One or more electromagnetic coils or permanent magnets 52, 54, 56 and 58 are arranged in the target region 22 to control the magnetic field in the target region 22. Similarly, one or more electromagnetic coils or permanent magnets 60 and 62 are arranged in the transfer region 24 to control the magnetic field in the transfer region 24. Likewise, one or more electromagnetic coils (not shown) or permanent magnets are arranged in the substrate region 30 to control the magnetic field in the substrate region 30.

According to the present disclosure, a magnetic field (potential) well 80 is created in the vicinity of the substrate 16 using N first and M second coaxial coils 100 and 110, respectively. The magnetic field well 80 is defined by a region that has an approximately zero magnetic field surrounded by a region having a very strong magnetic field. Charged species can move fairly freely inside the magnetic field well 80 but cannot easily escape.

Creating the magnetic field well 80 with an appropriate diameter (approximately equal to a diameter of the substrate 16) near the substrate 16 allows the ions to distribute freely over the substrate 16 while being confined to the volume spanned by the substrate diameter.

To create the magnetic field well 80, N first coaxial coils 100 with N first coaxial coil diameters are arranged below the substrate 16 in the substrate region 30, where N is an integer greater than zero. M second coaxial coils 110 with M second coaxial coil diameters are arranged above the substrate 16 in the target region 22, where M is an integer greater than zero. The N first coaxial coil diameters can be the same or different. The M second coaxial coil diameters can be the same or different.

In a first example, the diameters of the N first coaxial coils 100 are less than the diameters of the M second coaxial coils 110. For example only, diameters of the N first coaxial coils 100 may be approximately 8-12 inches and diameters of the M second coaxial coils 110 may be 16-30 inches, although other dimensions may be used. In another example, the N first coaxial coils 100 may have a diameter approximately equal to a diameter of the substrate 16 and the M second coaxial coils 110 may have a diameter that is T times the diameter of the substrate 16, where T is greater than or equal to 1.

A current supply 111 supplies N currents that flow in a first direction in each of the N first coaxial coils 100, respectively. The current supply 111 supplies M currents that flow in a second direction in each of the M second coaxial coils 110, respectively. The first direction is opposite to the second direction. In some examples, the sum of the magnetic fields generated by the N first coaxial coils is opposite to the sum of the magnetic fields generated by the M second coaxial coils. In other examples, when N or M are greater than one, the additional coils can be arranged radially outside of each other in the same plane or axially on top of each other.

When the N currents flow in opposite directions in the N first coaxial coils 100 with respect to the M currents flowing in the M second coaxial coils 110, the magnetic fields cancel inside the N first coaxial coil diameters and add outside of the N first coaxial coil diameters. With appropriate diameters and current magnitudes, the magnetic field well 80 can be created. The well radius can be adjusted by varying current magnitudes and the coaxial coil diameters.

Magnitudes of the M currents may be adjusted relative to magnitudes of the N currents. For example only, a smallest one of the M currents may be approximately two times a greatest one of the N currents. In addition, the N currents supplied to the N first coaxial coils may have the same or different current values. Likewise, the M currents supplied to the M second coaxial coils may have the same or different current values. For example only, the first and second coaxial coils 100, 110 may be spaced approximately the same distance below and above the substrate 16, respectively. In one example, the N first coaxial coils 100 and the M second coaxial coils 110 are arranged 0-6 inches below and above the substrate 16, respectively.

The creation of the magnetic field well 80 in the vicinity the substrate 16 results in a high density uniform plasma over the surface of the substrate 16, which leads to high quality uniform film deposition. The N first coaxial coils 100 below the substrate 16 and the M second coaxial coils 110 above the substrate 16 run opposite currents with respect to each other. By modulating the strength and dimension of the magnetic field well 80, uniform deposition and resputtering profiles can be achieved.

For example only, the PVD system 10 may deposit a tantalum/tantalum nitride (Ta/TaN) barrier film (upon which a copper (Cu) seed layer is deposited). The electroplated Cu is generally deposited on the seed layer using a different tool. The step coverage and uniformity of the barrier layer are improved.

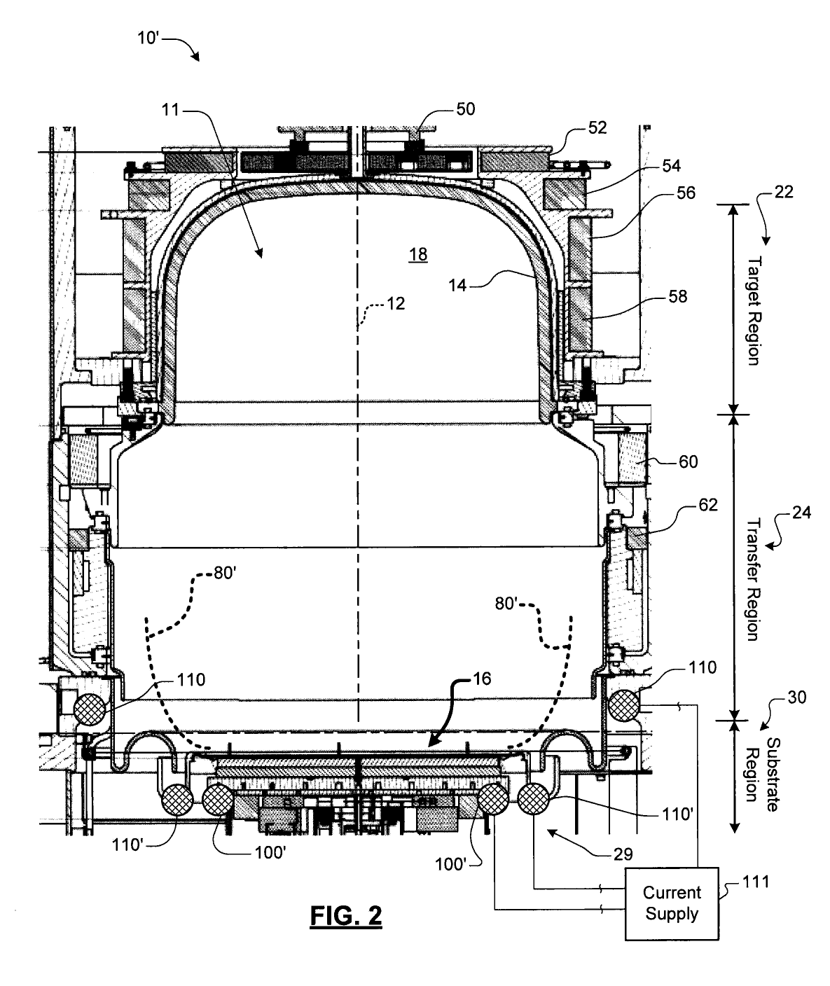

Referring now to FIG. 2, a PVD system 10′ is shown. As can be appreciated, N first coaxial coils 100′ and M second coaxial coils 110 and 110′ can be arranged in other locations relative to the substrate 16. For example in FIG. 2, the N first coaxial coils 100′ and one or more of the M second coaxial coils 110′ can be located in one or more planes below the substrate 16. If used, the remaining ones of the M second coaxial coils 110 may be located in a plane above the substrate as shown in FIG. 1. In other examples, all of the M second coaxial coils are arranged below the substrate.

When the N currents flow in opposite directions in the N first coaxial coils 100′ with respect to the M currents flowing in the M second coaxial coils 110 and 110′, the magnetic fields cancel inside the coil diameters and add outside of the coil diameters. With appropriate diameters and current magnitudes, the magnetic field well 80′ can be created. The radius of the magnetic field well 80′ can be adjusted by varying current magnitudes, coil position, and the first and second coaxial coil diameters.

For example, the N first and some of the M second coaxial coils 100′ and 110′ can be arranged approximately 0″-6″ below the substrate. In one example, the N first and some of the M second coaxial coils 100′ and 110′ can be arranged approximately 1″ below the substrate, the inner and outer diameters of the N first coaxial coils 100′ can be 12″/12.7″, respectively, and the inner and outer diameters of the M second coaxial coils 110′ can be 13.7″/14.7″, respectively, although other values may be used. As used herein, approximately refers to +/−0.25″. The remaining ones of the M second coaxial coils 110 may be arranged above the substrate as described above.

The N first coaxial coils 100′ and the M second coaxial coils 110′ run opposite currents with respect to each other. With the magnetic field generated by other coils or magnets (such as electromagnetic coils or permanent magnets 52, 54, 56, 58, 60 and/or 62), a magnetic potential well that is larger than the wafer size can be formed to facilitate plasma distribution.

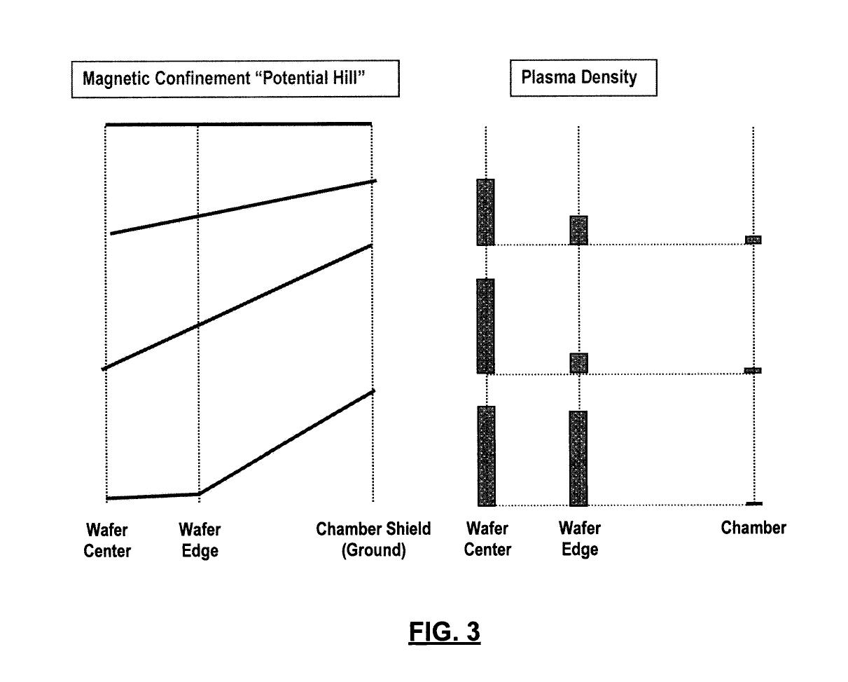

Referring now to FIG. 3, a cross-sectional view of the chamber 11, a first graph illustrating magnetic confinement potential and a second graph illustrating plasma density are shown. A controllable potential hill may be created using the N first and M second coaxial coils 100 and 110 (or 100′ and 110, 110′). A shape of the potential hill may be adjusted by varying magnitudes of current flowing through the M second coaxial coils 110 or 110′ and/or the N first coaxial coils 100 or 100′, a ratio of current flowing through the M second coaxial coils 110 or 110′ relative the N first coaxial coils 100 or 100′, the diameters of the N first coaxial coils 100 and/or the M second coaxial coils 110 (or 100′ and 110, 110′), and/or a ratio of the diameters of the N first coaxial coils 100 and the M second coaxial coils 110 (or 100′ and 110, 110′). The potential hill may be relatively constant across the substrate 16, or may have a constant or variable slope as desired.

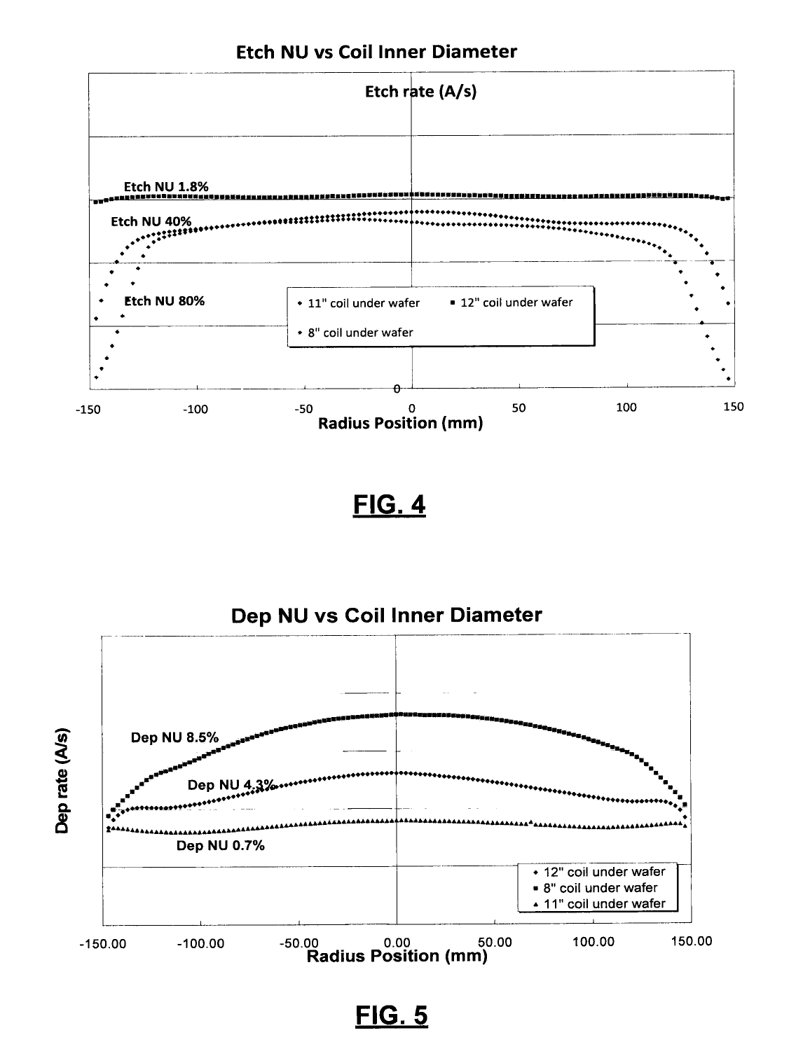

Referring now to FIGS. 4 and 5, more uniform etch and deposition rates are provided when the coaxial coil arrangement described above is used. In FIG. 4, etch rate in normalized units (NU) is shown as function of the diameter of the N first coaxial coils 100. In FIG. 5, deposition rate in NU is shown as function of the diameter of the N first coaxial coils 100. Improved deposition and etch symmetry across the substrate 16 is realized.

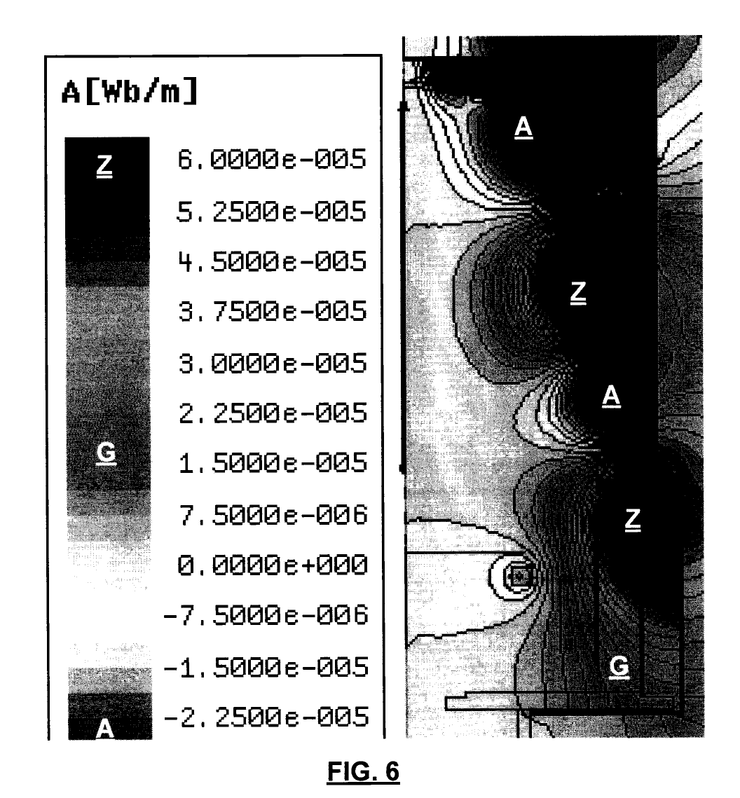

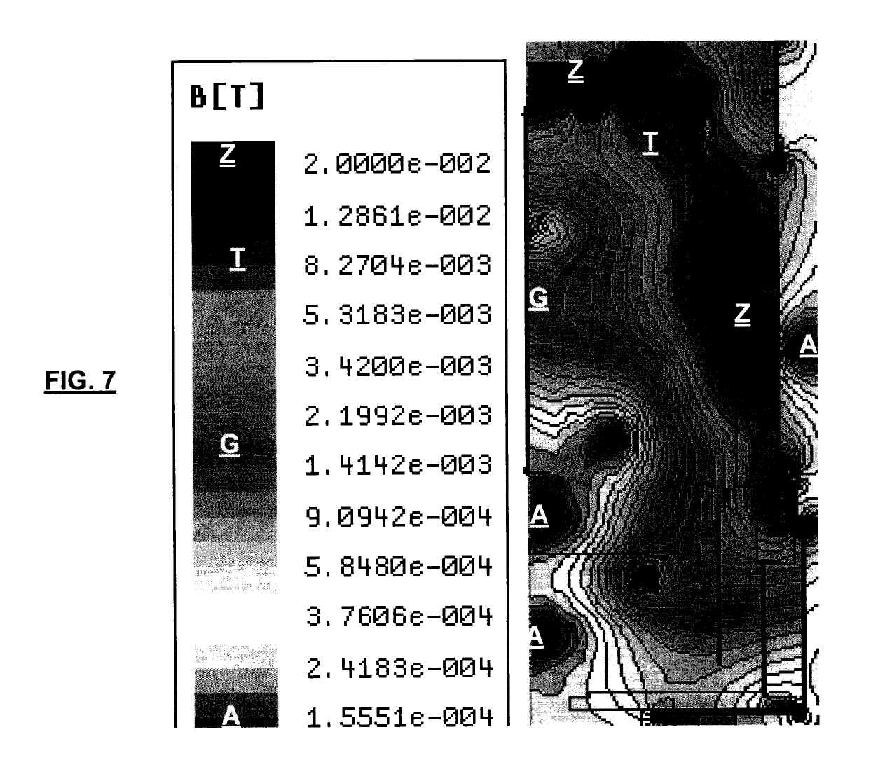

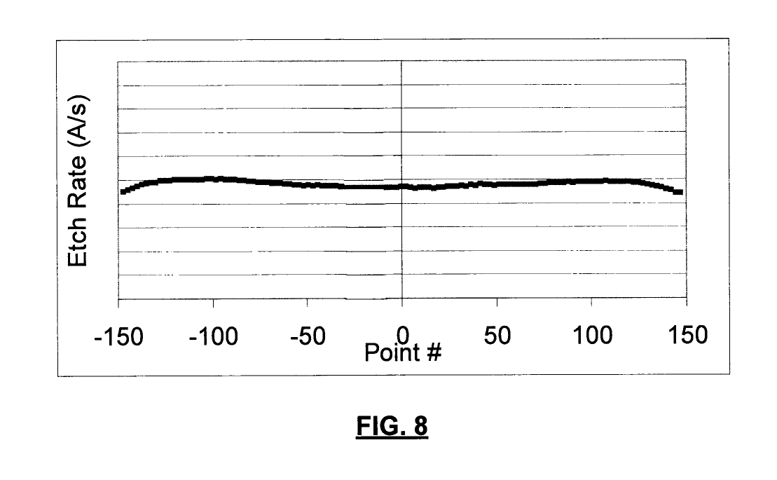

Referring now to FIGS. 6-8, another etch back process example is shown. In FIGS. 6 and 7, simulation plots show magnetic field strength and a magnetic well in the chamber with opposite electromagnetic coaxial coil polarities, respectively. In FIG. 8, an etch rate profile is shown. In this example, two circular nulls are created by alternating the polarity of the N first coaxial coils 100 and the M second coaxial coils 110. As the two null regions are close to each other, a magnetic field well 120 is formed. The substrate 16 is arranged close to a bottom of the magnetic field well 120. The magnetic strength simulation mapping in FIG. 6 shows a relative position of the magnetic field well 120 and the substrate 16. Within the near-zero magnetic field well 120, charged species are relatively free from the influence of a magnetic field, which results in excellent ion uniformity for resputtering applications. In FIG. 8, a line scan of etch rate profile across the substrate 16 is shown, which has excellent resputtering non-uniformity with 1-sigma standard deviation<3%.

The broad teachings of the disclosure can be implemented in a variety of forms. Therefore, while this disclosure includes particular examples, the true scope of the disclosure should not be so limited since other modifications will become apparent to the skilled practitioner upon a study of the drawings, the specification, and the following claims.

What is claimed is:

1. A physical vapor deposition (PVD) system, comprising:
a chamber;
a target arranged in a target region of the chamber;
a pedestal having a surface for supporting a substrate and arranged in a substrate region of the chamber, wherein a transfer region is located between the target region and the substrate region;
N coaxial coils arranged in a first plane parallel to the surface of the pedestal and below the pedestal; and
M coaxial coils, where N and M are integers greater than zero, and
wherein N currents flow in a first direction in the N coaxial coils, respectively, and M currents flow in a second direction in the M coaxial coils that is opposite to the first direction, respectively.

2. The PVD system of claim 1, wherein the M coaxial coils are arranged in a second plane that is parallel to the surface of the pedestal and above the surface of the pedestal.

3. The PVD system of claim 1, wherein the M coaxial coils are arranged in a second plane that is parallel to the surface of the pedestal and below the surface of the pedestal.

4. The PVD system of claim 1, wherein:
at least some of the M coaxial coils are arranged in a second plane that is parallel to the surface of the pedestal and below the surface of the pedestal, and
remaining ones of the M coaxial coils are arranged in a third plane that is parallel to the surface of the pedestal and above the surface of the pedestal.

5. The PVD system of claim 1, wherein the N coaxial coils and the M coaxial coils create a magnetic field well in the chamber above the substrate.

6. The PVD system of claim 5, wherein:
the magnetic field well is generally “U”-shaped and is centered on the surface of the pedestal;
a magnetic null is located inside the magnetic field well; and
a strong magnetic field is located outside of the magnetic field well.

7. The PVD system of claim 1, wherein:
at least one of the N coaxial coils has a first diameter,
at least one of the M coaxial coils has a second diameter, wherein the second diameter is greater than the first diameter.

8. The PVD system of claim 1, wherein N is greater than one and wherein at least one of the N currents has a different magnitude than another one of the N currents.

9. The PVD system of claim 1, wherein the target includes a hollow cathode magnetron (HCM).

10. The PVD system of claim 1, wherein a smallest one of the M currents is greater than a greatest one of the N currents.

11. The PVD system of claim 10, wherein a smallest one of the M currents is greater than or equal to approximately two times a greatest one of the N currents.

12. The PVD system of claim 2, wherein the N coaxial coils and the M coaxial coils are arranged 0-6 inches below and above the surface of the pedestal, respectively.

13. The PVD system of claim 4, wherein the N coaxial coils and the at least some of the M coaxial coils are coplanar.

14. The PVD system of claim 13, wherein the N coaxial coils and the at least some of the M coaxial coils are arranged 0-6 inches below the surface of the pedestal.

15. The PVD system of claim 14, wherein the N coaxial coils and the at least some of the M coaxial coils are arranged approximately 1 inch below the surface of the pedestal.

16. The PVD system of claim 1, wherein the PVD system is used to deposit a tantalum/tantalum nitride barrier film.

17. A method of operating a physical vapor deposition (PVD) system, comprising:
arranging N coaxial coils in a first plane parallel to a substrate-supporting surface of a pedestal in a chamber of a PVD system and below the pedestal;
arranging M coaxial coils adjacent to the pedestal, where N and M are integers greater than zero; and
creating a magnetic field well above a substrate by supplying N currents to the N coaxial coils, respectively, and M currents to the M coaxial coils, respectively,
wherein the N currents flow in a first direction in the N coaxial coils and the M second currents flow in a second direction in the M coaxial coils that is opposite to the first direction.

18. The method of claim 17, wherein arranging the M coaxial coils includes arranging the M coaxial coils in a second plane that is parallel to the surface of the pedestal and above the surface of the pedestal.

19. The method of claim 17, wherein arranging the M coaxial coils includes arranging the M coaxial coils in a second plane that is parallel to the surface of the pedestal and below the surface of the pedestal.

20. The method of claim 17, wherein arranging the M coaxial coils includes:
arranging at least some of the M coaxial coils in a second plane that is parallel to the surface of the pedestal and below the surface of the pedestal; and
arranging remaining ones of the M coaxial coils in a third plane that is parallel to the surface of the pedestal and above the surface of the pedestal.

21. The method of claim 17, wherein:
the magnetic field well is generally “U”-shaped and is centered on the substrate-supporting surface of the pedestal;
a magnetic null is located inside the magnetic field well; and
a strong magnetic field is located outside of the magnetic field well.

22. The method of claim 18, wherein:
at least one of the N coaxial coils has a first diameter, and
at least one of the M coaxial coils has a second diameter, wherein the second diameter is greater than the first diameter.

23. The method of claim 22, wherein N is greater than one and wherein at least one of the N currents has a different magnitude than another one of the N currents.

24. The method of claim 18, wherein the PVD system includes a hollow cathode magnetron (HCM) target.

25. The method of claim 18, wherein a smallest one of the M currents is greater than a greatest one of the N currents.

26. The method of claim 19, wherein the N coaxial coils and the M coaxial coils are arranged 0-6 inches below and above the surface of the pedestal, respectively.

27. The method of claim 18, wherein the N coaxial coils and the at least some of the M coaxial coils are coplanar.

28. The method of claim 27, wherein the N coaxial coils and the at least some of the M coaxial coils are arranged 0-6 inches below the surface of the pedestal.

29. The method of claim 28, wherein the N coaxial coils and the at least some of the M coaxial coils are arranged approximately 1 inch below the surface of the pedestal.

30. The method of claim 18, further comprising depositing a tantalum/tantalum nitride barrier layer.
